(19) United States
(12) Patent Application Publication
(10) Pub. No.: US 2002/0045349 A1
(43) Pub. Date: Apr. 18, 2002

(54) Method for chemical-mechanical-polishing a substrate

(76) Inventor: Robert L. Rhoades, Phoenix, AZ (US)

Correspondence Address: Rodel Holdings, Inc., Suite 1300, 1105 North Market Street, Wilmington, DE, 19899, US

(21) Appl. No.: 09/815,083

(22) Filed: Mar. 22, 2001

Related U.S. Application Data
(60) Provisional application No. 60/191,560, filed on Mar. 23, 2000.

(51) Int. Cl. H01L 21/302; H01L 21/461

(52) U.S. Cl. 438/691; 438/689

(57) ABSTRACT

A method of polishing a surface of a substrate wafer wherein slurry is recycled back to the interface between the polishing pad and the substrate surface during the polishing and newly-formulated slurry is supplied to the interface during the last stages of polishing. The method includes the application of a first slurry during the removal of first surface portion of the substrate, where at least a portion of the first slurry is recycled polishing slurry. At a predetermined transition point, the first slurry is replaced with a newly-formulated slurry and the newly-formulated slurry is applied to remove a second surface portion of the substrate.

### CROSS REFERENCE TO RELATED APPLICATION

This application claims the benefit of U.S. Provisional Application Serial No. 60/191,560 filed Mar. 23, 2000.

### FIELD OF THE INVENTION

The present invention relates, generally, to methods of operating a chemical-mechanical-polishing apparatus and, more particularly, to methods for polishing substrates, such as semiconductor wafers.

### BACKGROUND

Chemical-mechanical-polishing (CMP) generally consists of the controlled abrasion of an initially rough surface in order to produce a specular finished surface free from fracture, scratches, and other defects and of a smoothness approaching the atomic level. This is commonly accomplished by rubbing a pad against the surface of the article to be polished (the workpiece) in a rotary motion in combination with a solution containing a suspension of fine submicron particles (the slurry). Commonly employed pads are made from felted wool, urethane-impregnated felted polyester, or various types of polyurethane plastic.

The polishing rate for such a system is determined by several parameters including, the pressures and velocities employed as well as the concentration of slurry particles in contact with the workpiece at any given time. In order to ensure high and uniform polishing rates, polishing pads are commonly textured to improve slurry flow across the workpiece surface. In addition, the reduction in the contact surface area effected by patterning provides higher contact pressures during the early portion of a polishing process, further enhancing the polishing rate. Most polishing pads require the simultaneous use of a particle-containing slurry or a reactive liquid to achieve a detectably high polishing rate; the pad used by itself produces no significant removal or smoothing even when a particle-free liquid is used.

A common practice in many industrial applications of polishing is to reuse or recirculate the polishing slurry to reduce both the manufacturing cost and the quantity of waste products associated with a polishing operation. For example, recirculation of cerium oxide based slurries is commonly employed in the optical industry. However, the activity of a polishing slurry is commonly observed to vary with time when the slurry is recirculated. This may be due to the addition of dross, or polishing byproducts from the substrate into the slurry solution, attrition or breakdown of the polishing particles themselves during use, or chemical changes in the particles which reduce activity.

Slurry recycling has also been developed for use in polishing of semiconductor substrates. For example, the recycling of particle-containing slurries is disclosed in a series of European Patent Applications Nos. 849,040; 849,041; and 849,778. These applications disclose filtration of slurry; temperature adjustment of slurry; and adjustment of pH and redox potential, respectively. In U.S. Pat. No. 6,028,006 the pH adjustment of a slurry comprising particles of silica in water stabilized by sodium cations is disclosed. Further, U.S. Pat. No. 5,664,990 discloses the mixing of recycled slurry and fresh slurry during a polishing process.

In the field of microelectronic fabrication, the amount of variation in recirculated slurries can be unacceptably high for the processing of semiconductor devices. In the polishing of most semiconductor devices, the need to control polishing activity precisely and to avoid damage by contaminants outweighs the cost benefit of recirculated slurry. For example, a major application of polishing of semiconductor substrates is the polishing of SiO₂ surface films using slurries containing SiO₂ particles. Slurry recirculation of this application is exceedingly difficult because the byproducts of the polishing process are coagulated SiO₂ particulates derived from in situ polymerization of waste products in the slurry. These are practically impossible to distinguish from the original slurry particles, and it is extremely difficult to control their size or remove them from the solution. In consequence, the solid particle content of the recirculated slurry continuously increases with time. Since the polishing rate is directly proportional to the solids content of the slurry, practical control of the polishing rate and across-wafer uniformity is difficult. Additional problems encountered with the use of recycled slurry include the accidental incorporation of oversized contaminant particles into the recirculating slurry. The oversized particles can be particulate matter from substrate breakage or dried agglomerates that break off from various surfaces of the polishing apparatus or drain lines attached to the polishing apparatus.

The result of particle contamination in recycled slurry can be scratching of the semiconductor substrate surface and increased surface roughness. Other deleterious surface effects include dishing, isolated erosion areas, and a possible loss in polishing selectivity to the polishing of a particular layer on the semiconductor substrate. Also, the presence of contaminant particles and residual materials, such as metals, organic residues, and the like, can lead to increased contamination of the semiconductor substrate surface that lingers even a after post-CMP clean steps.

To avoid the problems associated with the use of recycled slurry, often the slurry is simply used once and disposed of as waste. As a result, the cost of slurry and slurry waste disposal is the single largest contributor to the cost of polishing semiconductor devices. Accordingly, an improved polishing process is necessary to take advantage of the cost saving afforded with use of recycled slurry, while avoiding many of the problems inherent with the use of recycled slurries.

### BRIEF SUMMARY

The deficiencies of the prior art are overcome in the present invention by supplying a method of polishing a surface of a semiconductor wafer comprising the steps of:

(a) holding said wafer in a carrier;

(b) providing a polishing pad having a polishing surface and a multiplicity of nanoasperities in the polishing surface;

(c) moving said carrier to contact said polishing surface with said wafer surface and to provide both pressure on said wafer surface and relative lateral motion between said wafer surface and said polishing surface; and

(d) delivering a polishing slurry to the interface between the wafer surface and the polishing surface,

wherein said polishing slurry exiting said interface is recycled and returned to said interface and

wherein at the end of a polishing cycle said polishing slurry is no longer recycled, but is provided as newly formulated slurry.

Adjustment of the slurry while being recycled may be carried out. Monitoring and adjustment of composition, pH, redox potential, and any other chemical property of the slurry may be carried out before the recycled slurry is returned to the polishing interface. Physical changes, such as the removal of large particles and agglomerates, may also be made in the recycled slurry.

### BRIEF DESCRIPTION OF THE DRAWINGS

FIG. 1 is a schematic diagram of a prior art polishing apparatus;

FIG. 2 is a schematic diagram of a polishing apparatus for carrying out a polishing process in accordance with one embodiment of the invention;

FIG. 3 is a schematic diagram of another polishing apparatus for carrying out the polishing process in accordance with the invention;

FIG. 4 is a flow chart for a slurry treatment process in accordance with the invention;

FIGS. 5A and 5B illustrate, in cross-section a substrate positioned in a polishing apparatus at two stages in a polishing process carried out in accordance with the invention; and

FIG. 6 is an exemplary plot of end-point signal intensity versus time for a polishing process carried out in accordance with the invention.

### DETAILED DESCRIPTION OF PREFERRED EMBODIMENTS

The present invention is for a method of polishing a substrate surface using a recycled polishing slurry in which the final polishing phase is carried out with a newly-formulated and previously unused slurry. The method of the invention takes advantage of the cost saving associated with the use of recycled, particle-containing type slurry, while insuring that the quality of the polished surface will not be compromised by the use of a recycled slurry. By providing a previously unused (virgin) slurry during the final stages of polishing of a semiconductor wafer, a polishing process having stable performance during the entire polishing process and generating minimal defects in a semiconductor substrate is realized. A commonly-assigned, related application that discloses a process using a recycled particle-free slurry and having Ser. No. 09/498,267 is incorporated herein.

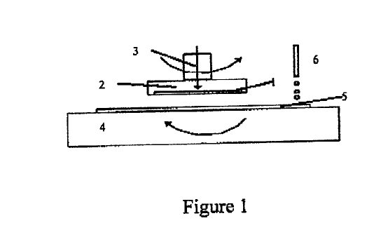

A wide variety of apparatus for polishing purposes have been previously disclosed. The most common type, typified by U.S. Pat. Nos. 4,141,180; 4,680,893 and 4,918,870, is comprised of the following features, as illustrated in FIG. 1. The wafer 1 is held by a fixture, or carrier 2, which is mounted on a rotatable spindle 3. This rotating carrier assembly is pressed against a rotating table 4 on whose upper surface is affixed a polishing pad 5. The simultaneous rotation of carrier and table effects a lateral movement of the pad against the wafer surface. When slurry is fed onto the pad surface 6, the lateral motion in conjunction with the slurry particles effects the polishing action. Most other prior art polishing apparatus designs use the same basic principle, with lateral motion of pad and wafer being effected by several different means including linear motion (see U.S. Pat. No. 5,487,697) and ultrasonic vibration (see U.S. Pat. No. 5,245,796).

In the practice of the present invention, the particular slurry employed for each type of substrate will be different and optimized for the particular substrate. Thus a wide variety of slurries may be employed. Also, filtration of particulate contaminants resulting from pad wear, substrate polishing byproducts, or external contaminants is easily performed with conventional filtration equipment on recycled slurry. The filtration of the slurry reduces the probability of scratching or other damage to the substrate being polished and facilitates substrate polishing with virgin slurry at the end of a polishing cycle.

Another advantage of the present invention is the ease with which the slurry can be treated to preserve its activity and monitor its critical properties. For example, the pH and concentration of slurry components may be precisely measured in situ before and after use by the use of pH and specific ion electrodes. Provisions for addition of additional chemicals into the slurry as needed to maintain a constant concentration and pH can be easily introduced into the recirculation system.

For the case where the reactive liquid solution relies on metal passivation effects for activity, similar measurement and control systems may be employed. For example, if the reactive liquid solution for metal polishing consisted of about 50 ppm Ozone in water at pH of about 4, the oxidation potential of the solution (which is directly proportional to the ozone concentration) and the pH may be measured at any point in a recirculation loop with conventional electrodes. Provisions for addition of additional acid and ozone into the solution as needed to maintain constant pH and oxidation potential can then be easily introduced into the recirculation system.

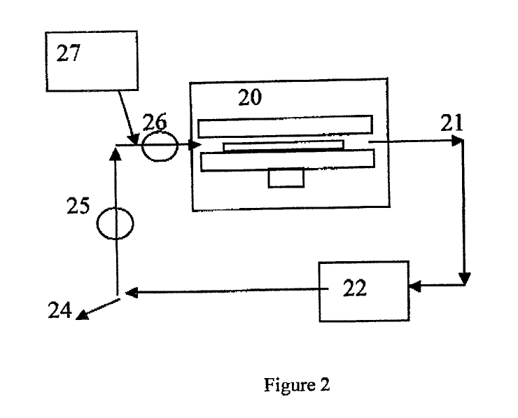

In accordance with the invention, all of these elements described above can be combined into a polishing system which permits closed loop recirculation of a polishing slurry. A schematic diagram of a polishing system arranged in accordance with one embodiment of the invention is illustrated in FIG. 2. The polishing is performed using apparatus 20, which includes a table and pad contacting the substrate together with a reactive liquid solution. A recirculation line 21 carries the used slurry to a filter 22 for removal of large particle contaminants from the slurry. Any excess liquid may be sent off as waste through a waste line 24. Following contaminant removal the properties of the reactive liquid solution may be measured via sensors 25, and adjusted with fresh chemical additives 27 to yield a slurry of properties more nearly equivalent to a fresh slurry. The final properties of the slurry may be measured via a second set of sensors 26 prior to slurry re-use. In the final stages of polishing, slurry 21 exiting apparatus 20 will be removed entirely from the system via waste line 24 and fresh slurry will be introduced at 27.

It may be appreciated that such an apparatus lends itself to closed loop control of properties with corresponding reductions in labor cost and variability. It should also be noted that this example is only illustrative of the concepts; a wide variety of particular systems can be constructed to fit the particular needs at hand by one skilled in the art.

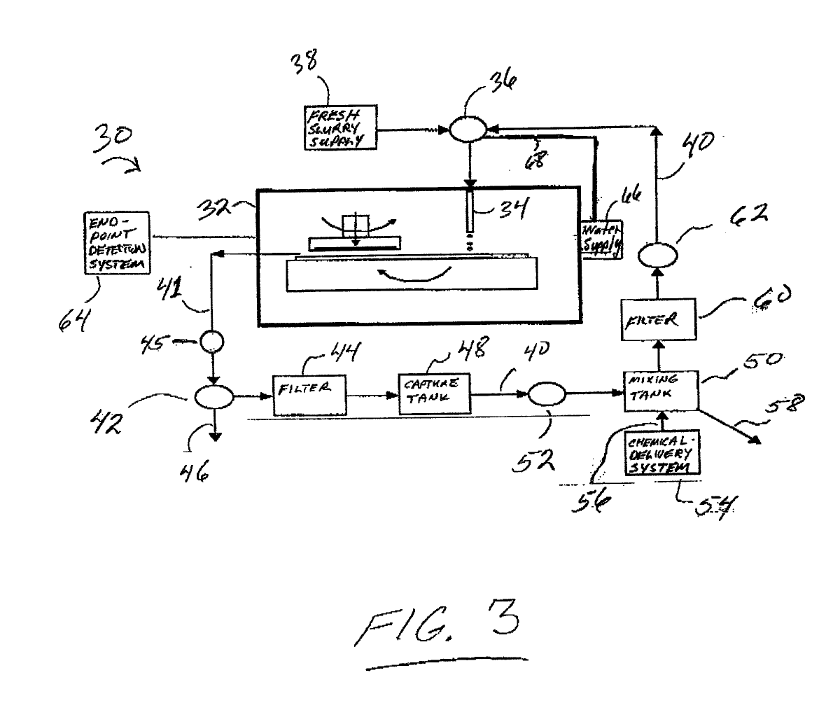

Another polishing apparatus 30 for carrying out the process of the invention is illustrated in FIG. 3. Apparatus 30 includes a workstation 32 that includes the operative components of a CMP apparatus as described and illustrated in FIG. 1. Workstation 32 is equipped with a slurry feed 34 connected to a selector valve 36. Selector valve 36 is configured to receive newly-formulated slurry from a fresh slurry supply 38 and recycled slurry through a slurry recirculation line 40. Used slurry is withdrawn from workstation 32 through used slurry line 41 and flows to a diverter valve 42. Diverter valve 42 can be actuated to transfer recycled slurry flowing in used slurry line 41 to either an initial filter 44 or to a drain line 46. The used slurry can be monitored by a sensor 45 to detect a physical or chemical property of the used slurry, such as solids content or pH value, or the like. Upon the detection of an unacceptable condition in the used slurry, sensor 45 can activate diverter valve 42 to send the used slurry to drain 46, rather than to initial filter 44.

The used slurry flowing through initial filter 44 is transferred to a capture tank 48 through recirculation line 40. The used slurry is transferred from capture tank 48 to a mixing tank 50 while being monitored by a first sensor 52 positioned in slurry recirculation line 40 between capture tank 48 and mixing tank 50. Make-up chemicals can be added to mixing tank 50 from a chemical delivery system 54 coupled to mixing tank 50 through a feed line 56. Mixing tank 50 is also equipped with a drain line 58. In returning to selector valve 36, the recycled slurry is transported through a final filter 60 and a second sensor 62.

In operation, selector valve 36 can be adjusted to feed either recycled slurry from slurry recirculation line 40 or newly-formulated slurry from fresh slurry supply 38 to a slurry feed 34. Additionally, selector valve 36 can be positioned to deliver a blended slurry to slurry feed 34. Selector valve 36 can be operated in a manner to deliver a blended slurry to slurry feed 34 having any desired blend composition ranging from 100% recycled slurry to 100% newly-formulated slurry. The particular blend composition will depend several factors, including the desired polishing rate, the desired polishing selectivity, the desired sensitivity to various substrate surface properties for a given substrate composition and the like.

As will subsequently be described in more detail, an end-point detection system 64 monitors the progress of the polishing process. Selector valve 36 can be activated by electronic control from end-point detection system 64 to adjust the ratio of fresh to recycled slurry, or to terminate the flow of slurry in slurry feed 34. At the end of the polishing process, a water rinse is provided to feed 34 from a water supply 66 through a rinse line 68.

During operation, the recycled slurry flowing in slurry recirculation line 40 is continuously monitored by first sensor 52 and second sensor 62. Those skilled in the art will appreciate that sensors 52 and 62 can be configured to monitor a variety of physical and chemical parameters of the recycled slurry. In particular, sensors 52 and 62 can monitor the pH, the chemical composition, the presence and particle size of solids in the slurry, and the like. Those skilled in the art will also appreciate that additional sensors can be positioned within polishing apparatus 30 at various locations. Further, sensors 52 and 62 can be positioned in different locations than those illustrated in FIG. 3.

Filters 44 and 60 function to remove contaminant particles and particulate matter from the recycled slurry. Typically, the first filter 44 includes a simple mesh or trap to prevent broken substrate material and unwanted debris from entering the recycled slurry stream. Those skilled in the art will appreciate that numerous filter designs are useful for removing unwanted contaminants, such as multi-stage filters and the like.

Polishing apparatus 30 can be operated without the return of recycled slurry by opening diverter valve 42 and simply draining all of the slurry removed from workstation 32 through drain line 46. The recycled slurry passing through initial filter 44 is captured in capture tank 48 where a volume of slurry can be accumulated and measured by first sensor 52 prior to or during transfer to mixing tank 50. In mixing tank 50, the solid particle concentration of the recycled slurry can be increased if needed by adding an appropriate amount and type of abrasives or abrasive concentrate. Similarly, in mixing tank 50, the solid particle concentration of the recycled slurry can be lowered if needed by adding an appropriate amount of deionized water or other suitable diluent. Additionally, any chemical deficiencies are rectified by introduction of fresh chemical components in mixing tank 50. Drain line 58 can be used to dump the contents of mixing tank 50 in the event that the recycled slurry does not meet a predetermined specification. Activating drain line 58 insures that unsatisfactory slurry is not returned to workstation 32.

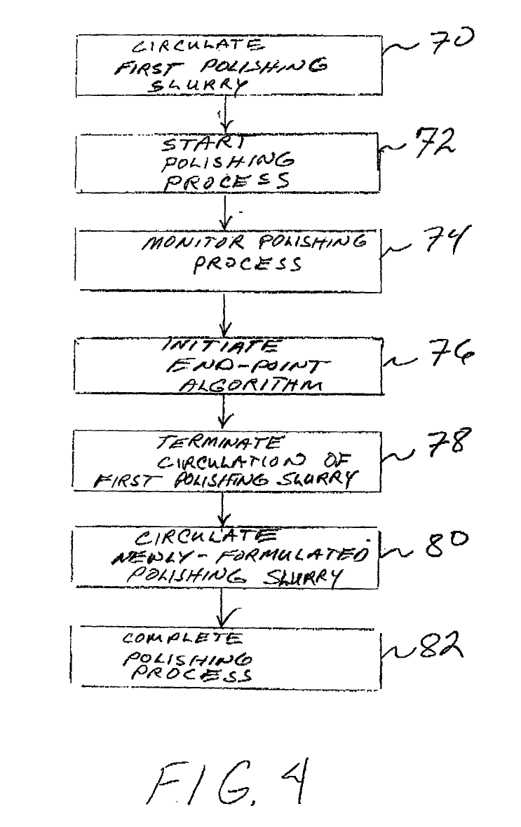

A flowchart for a method of polishing a substrate surface, in accordance with one embodiment of the invention, is illustrated in FIG. 4. The process of the invention is preferably carried out in a polishing apparatus, such as polishing apparatus 30 illustrated in FIG. 3. Alternatively, the process of the invention can be carried out in any of a number of different polishing system configurations. For example, rather than a rotating platen-type polishing system, a belt-type polishing apparatus can also be used. Further, the process of the invention can be carried out in a polishing apparatus having more than one workstation.

For example, the process of the invention can be carried out in a polishing apparatus in which initial polishing is performed on a first platen and subsequent polishing is carried out on a second platen or even a second and a third platen. In such a process, all or a portion of workstation 32 is duplicated. Each workstation can be facilitated with slurry recirculation line 40, fresh slurry supply 38 and selector valve 36. Alternatively, where initial polishing is to be performed with recycled slurry on a first platen and final polishing is to be performed on a second or third platen, the first platen does not need a fresh slurry supply. Those skilled in the art will recognize that numerous variations of a multiple workstation process are possible, and that those variations are within the scope of the present invention

In accordance with the process of the invention, a first polishing slurry is circulated through a polishing system at step 70. The first polishing slurry can be a polishing slurry composed of 100% recycled polishing slurry. For example, the circulation of a first polishing slurry at step 70 can be carried out by adjusting selector valve 36 such that the slurry fed to slurry feed 34 does not contain any newly-formulated slurry from fresh slurry supply 38. Alternatively, the circulation of a first polishing slurry at step 70 can be carried out by providing a blended slurry composed of a mixture of newly-formulated slurry and recycled slurry.

Once a circulation of the first polishing slurry is established, a polishing process is initiated at step 72. During the polishing process, the slurry is continuously analyzed, for example, by sensors 52 and 62 at step 74. As part of the monitoring process, an end-point algorithm is initiated within end-point detection system 64 at step 76. End-point detection system 64 can be one of a number of different kinds of end-point detection systems commonly used in CMP systems. For example, the end-point detection system can be an optical system, an acoustic system and the like. The end-point algorithm operates on signals collected and processed by the end-point detection system. As will subsequently be described in more detail, the end-point algorithm determines the approach of an end-point in the polishing process.

At a predetermined period during the polishing process, the circulation of the first polishing slurry is terminated at step 78. The termination of the circulation of the first polishing slurry can be accomplished by, for example, readjusting the position of selector valve 36, such that a higher percentage of newly-formulated slurry is delivered to slurry feed 34 from fresh slurry supply 38. In accordance with the invention, the adjustment in the composition of the slurry can be carried out by a number of different methods. For example, the slurry composition can be slowly altered in stages over a period of time or, alternatively, the composition can be swiftly changed from pure recycled slurry or a blended slurry to pure newly-formulated slurry. The exact composition adjustment sequence that is carried out will depend upon factors, such as the particular substrate material being polished, whether a multi-stage polishing process is being carried out, the particular chemical composition of the slurry and the like. In accordance with one embodiment, the ratio of fresh to recycled slurry is steadily increased as the polishing process progresses.

Those skilled in the art will appreciate that, in the case of the selective polishing of a selected material in the presence of other non-selected materials, that the polishing slurry composition can be changed to vary the selectivity of the slurry during the polishing process. Furthermore, in the case of a multi-stage polishing process, the slurry composition can be altered as different layers of material are polished on the substrate.

Regardless of whether or not a single-stage polishing process or a multi-stage polishing process is carried out, or whether or not a selective polishing process is carried out, the final polishing is performed at step 80 by circulating a newly-formulated polishing slurry. In accordance with the invention, the final polishing step operates to minimize deleterious effects to the substrate caused by the use of a recycled polishing slurry. As described above, numerous defects can be created on a substrate surface from the use of a recycled polishing slurry. A particular advantage of the present invention relates to the use of a newly-formulated polishing slurry at the final stage of the polishing process. By using a newly-formulated polishing slurry at the very end of the process, any surface defects arising from the use of a recycled slurry can be eliminated at the final stage of the polishing process. Accordingly, a polishing process, carried out in accordance with the invention, can leave the surface of the substrate in the same condition as though only newly-formulated polishing slurry had been used during the entire polishing process. By switching to a newly-formulated polishing slurry at the final stage of the process, a polishing process carried out, in accordance with the invention, can benefit from cost savings associated with the use of recycled slurry while avoiding the deleterious surface effects often encountered from the use of such a recycled polishing slurry.

The polishing process is completed at step 82. In accordance with one embodiment of the invention, a simple liquid rinsing step can be carried out, for example, by activating water supply 66 to rinse away the final portions of polishing slurry from the substrate prior to removing the substrate from the polishing apparatus. Additionally, other chemicals can be introduced, if necessary, to stabilize or coat the freshly-polished substrate surface. In one operational method, at the time that water supply 66 is activated, diverter valve 42 is opened to send the used slurry in line 41 to drain 46.

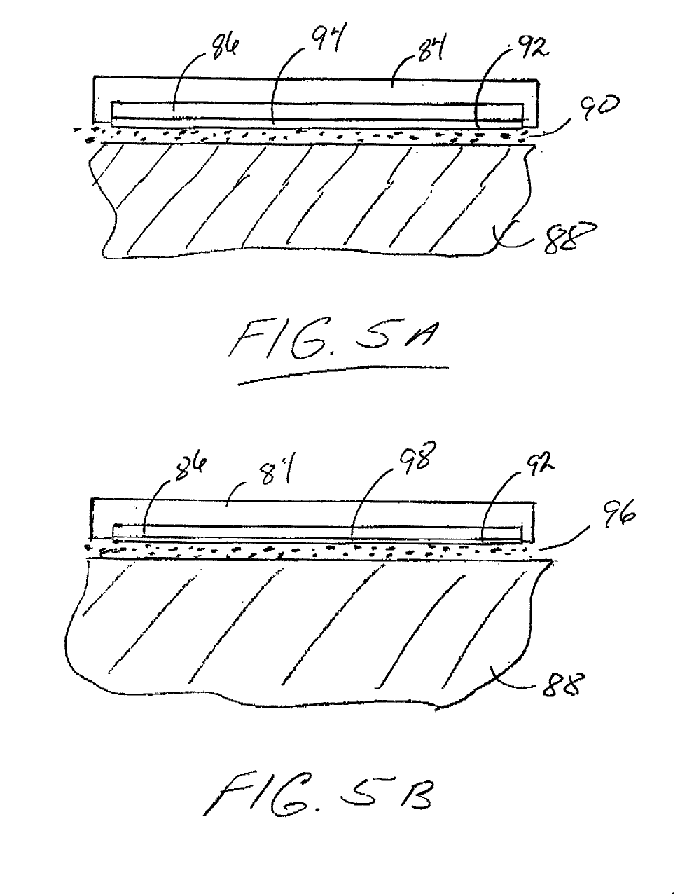

Two stages of a polishing process, carried out in accordance with the invention, are illustrated in the cross-sectional views of FIGS. 5A and 5B. A carrier 84, which is mounted to a rotatable spindle (not shown) holds a semiconductor substrate 86. Carrier 84 presses semiconductor substrate 86 against a polishing pad 88 while a first polishing slurry 90 is dispensed onto polishing pad 88. First polishing slurry 90 contacts a substrate surface 92 of semiconductor substrate 86. During the polishing process illustrated in FIG. 5A, a first thickness 94 of substrate surface 92 is removed by operation of the first polishing slurry in conjunction with a relative lateral motion created between semiconductor substrate 86 and polishing pad 88.

At a predetermined point in time, the flow of first polishing slurry 90 is terminated and a newly-formulated polishing slurry 96 is dispensed onto polishing pad 88, as illustrated in FIG. 5B. During this portion of the polishing process, a second thickness 98 of substrate surface 92 is removed. Importantly, second substrate surface thickness 98 represents the final portion of semiconductor substrate 86 removed during the polishing process.

Those skilled in the art will recognize that a variety of polishing processes can be carried out using the method of the invention. For example, regions 94 and 98 of semiconductor substrate 86 can represent different material layers overlying semiconductor substrate 86. For example, element 94 can be a metal layer and element 98 can be a polish stop layer. Accordingly, first polishing slurry 90 is used to remove a metal layer overlying a polish-stop layer. Once the metal layer is removed, the polishing process continues with freshly-formulated polishing slurry 96 to complete the final removal of any remaining portions of the metal layer overlying the polish-stop layer.

The transition point at which first polishing slurry 90 is replaced with newly-formulated polishing slurry 96 can be determined using a variety of techniques. In a preferred embodiment of the invention, the total polishing time to remove both first substrate thickness 94 and second substrate thickness 98 is determined. Preferably, the transition point is selected to correspond to about 20% to about 90% of the total polishing time and, more preferably, about 60% of the total polishing time.

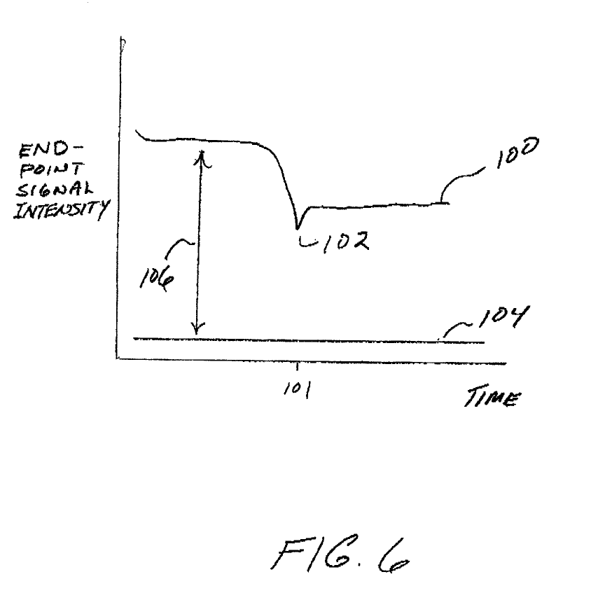

In accordance with an alternative embodiment of the invention, the transition point can be determined by activation of an end-point algorithm. An exemplary plot of end-point signal intensity versus time is illustrated in FIG. 6. The end-point detection system continuously monitors the polishing operation and generates an output signal 100. As the polishing process progresses, the output signal intensity changes abruptly as an end-point 102 is reached. In accordance with one embodiment of the invention, the first polishing slurry is terminated and the flow of the newly-formulated polishing slurry takes place at a transition point 101 corresponding to end-point 102.

In an alternative method, a baseline signal 104 is established and a range 106 is determined between an initial portion of output signal 100 and baseline signal 104. The intensity level of output signal 100 is continuously monitored and compared with the baseline signal 104 and a difference value continuously computed. The end-point can then be defined as a point in time when the difference value becomes a predetermined percentage of the range 106. In accordance with one embodiment of the invention, the end-point is defined as a point in time when the difference value is preferably about 20% to about 99% of range 106 and, more preferably, about 60% to about 70% of range 106.

Thus, it is apparent that there has been disclosed, in accordance with the invention, a method for polishing a substrate that fully provides the advantages set forth above. Although the invention has been described and illustrated with reference to specific, illustrative embodiments thereof, it is not intended that the invention be limited to those illustrative embodiments. Those skilled in the art will recognize that variations and modifications can be made without departing from the spirit of the invention. For example, the temperature of the newly-formulated slurry or the recycled slurry, or both, can be controlled in the polishing apparatus. It is, therefore, intended to include within the invention all such variations and modifications as fall within the scope of the appended claims and equivalents thereof.

1. A method of polishing a surface of a semiconductor wafer comprising the steps of:
(a) holding said wafer in a carrier;
(b) providing a polishing pad having a polishing surface and a multiplicity of nanoasperities in the polishing surface;
(c) moving said carrier to contact said polishing surface with said wafer surface and to provide both pressure on said wafer surface and relative lateral motion between said wafer surface and said polishing surface; and
(d) delivering a polishing slurry to the interface between the wafer surface and the polishing surface,
wherein said polishing slurry exiting said interface is recycled and returned to said interface and
wherein at the end of a polishing cycle said polishing slurry is no longer recycled, but is provided as newly formulated slurry.

2. The method of claim 1 wherein said recycled slurry is monitored for composition and adjusted in composition before being returned to said interface.

3. The method of claim 1 wherein said recycled slurry is monitored for pH and adjusted in pH before being returned to said interface.

4. The method of claim 1 wherein said recycled slurry has large particles removed before being returned to said interface.

5. A method of polishing a substrate surface comprising:
providing a polishing surface;
providing a first polishing slurry, wherein at least a portion of the first polishing slurry comprises a recycled polishing slurry;
providing a newly-formulated polishing slurry;
contacting the substrate surface with the polishing surface and removing a first thickness of the substrate surface, while applying the first polishing slurry to the substrate surface;
terminating the application of the first polishing slurry; and
removing a second thickness of the substrate surface, while applying the newly-formulated polishing slurry to the substrate surface.

6. The method of claim 5 further comprising completing the polishing process by applying a water rinse to the substrate surface after terminating the application of the newly-formulated polishing slurry.

7. The method of claim 5, wherein terminating the application of the recycled polishing slurry further comprises monitoring the removal of the first thickness and selecting a transition point in time for terminating the application of the recycled polishing slurry.

8. The method of claim 7, wherein monitoring the removal of the first thickness comprises determining a total polishing time for removing the first thickness of the substrate surface.

9. The method of claim 8, wherein selecting the transition point in time comprises selecting a time from within a range corresponding to about 20% to about 90% of the total polishing time.

10. The method of claim 8, wherein selecting the transition point in time comprises selecting a time corresponding to about 60% of the total polishing time.

11. The method of claim 7 further comprising providing an end-point detection system, and wherein monitoring the removal of the first thickness comprises activating the end-point detection system.

12. The method of claim 1, wherein removing a first thickness of the substrate surface comprises removing a first portion of a material layer, and wherein removing a second thickness of the substrate surface comprises removing a second portion of the material layer.

13. The method of claim 1, wherein removing a first thickness of the substrate surface comprises removing a first material layer, wherein the first material layer overlies a second material layer.

14. A polishing process for polishing a substrate comprising the steps of:
providing a polishing apparatus having a polishing pad;
pressing the substrate against the polishing pad and creating a relative lateral motion between the substrate and the polishing pad, while circulating a first polishing slurry in the polishing apparatus, wherein at least a portion of the first polishing slurry comprises a recycled polishing slurry;
terminating the circulation of the first polishing slurry; and
circulating a newly-formulated polishing slurry in the polishing apparatus until terminating the polishing process.

15. The polishing process of claim 14, wherein circulating a first polishing slurry comprises blending recycled slurry with fresh chemical additives, such that the concentration of fresh chemical additives in the recycled slurry increases while circulating the first polishing slurry.

16. The polishing process of claim 14, wherein terminating the circulation of the recycled polishing slurry further comprises removing a first thickness and a second thickness of the substrate surface and selecting a transition point in time for terminating the circulation of the first polishing slurry.

17. The polishing process of claim 16, wherein removing the first thickness comprises determining a total polishing time for removing the first thickness and the second thickness of the substrate surface.

18. The polishing process of claim 17, wherein selecting the transition point in time comprises selecting a time from within a range corresponding to about 20% to about 90% of the total polishing time.

19. The polishing process of claim 17, wherein selecting the transition point in time comprises selecting a time corresponding to about 60% of the total polishing time.

20. The polishing process of claim 14 further comprising providing an end-point detection system, and wherein terminating the circulation of the recycled polishing slurry comprises monitoring an output signal of the end-point detection system and terminating the circulation of the first polishing slurry upon detection of an end-point in the output signal.

21. The polishing process of claim 20, wherein monitoring the output signal comprises the steps of:
establishing a base line signal level and an end-point signal level and determining a range, wherein the range is the absolute difference between the base line signal level and the end-point signal level;
comparing the output signal with the base line signal and computing a difference value between the output signal and the base line signal; and
defining the end-point as a point in time when the difference value is about 20% to about 99% of the range.

22. A method of polishing a substrate surface comprising:
providing a first polishing slurry, wherein at least a portion of the first polishing slurry comprises a recycled polishing slurry;
providing a newly-formulated polishing slurry;
removing a first thickness of the substrate surface, while applying the first polishing slurry to the substrate surface; and
removing a second thickness of the substrate surface, while applying the newly-formulated polishing slurry to the substrate surface.

23. The method of claim 22, wherein removing a first thickness comprises providing a polishing surface and contacting the substrate surface with the polishing surface.

24. The method of claim 22, wherein removing a second thickness comprises providing a polishing surface and contacting the substrate surface with the polishing surface.

25. The method of claim 22 further comprising applying the newly-formulated polishing slurry until terminating the polishing process.

26. The method of claim 22, wherein removing a first thickness comprises providing a first polishing surface and contacting the substrate surface with the first polishing surface and wherein removing a second thickness comprises providing a second polishing surface and contacting the substrate surface with the second polishing surface.
